(19) United States
(12) Patent Application Publication
(10) Pub. No.: US 2018/0169608 A1
(43) Pub. Date: Jun. 21, 2018

(54) UTILIZATION OF AMBIENT THERMAL ENERGY

(71) Applicant: Mohammad Faran SIDDIQUI, Mississauga (CA)

(72) Inventor: Mohammad Faran SIDDIQUI, Mississauga (CA)

(21) Appl. No.: 15/846,354

(22) Filed: Dec. 19, 2017

Related U.S. Application Data
(60) Provisional application No. 62/437,329, filed on Dec. 21, 2016.

(51) Int. Cl. B01J 19/24; H01L 35/30

(52) U.S. Cl. CPC B01J 19/24; B01J 2219/24; H01L 35/30

(57) ABSTRACT

There is provided a method of harnessing ambient thermal energy including: conducting an endothermic reaction in thermal contact with a first heat sink to generate one or more reaction products and conducting an exothermic reaction in thermal contact with a second heat sink using at least one of the one or more reaction products. The conducting the endothermic reaction and the conducting the exothermic reaction generates a temperature difference between the first heat sink and the second heat sink.

### CROSS-REFERENCE TO RELATED APPLICATION

This application claims the benefit of U.S. Provisional Patent Application No. 62/437,329, filed on Dec. 21, 2016, which is incorporated herein by reference in its entirety.

### FIELD

The present specification relates to methods for harnessing ambient thermal energy, and in particular to methods for harnessing ambient thermal energy using endothermic and exothermic reactions.

### BACKGROUND

Energy is needed to perform useful work. The ambient environment can contain various forms of energy, including thermal energy.

### SUMMARY

According to an aspect of the present specification there is provided a method of harnessing ambient thermal energy including: conducting an endothermic reaction in thermal contact with a first heat sink to generate one or more reaction products and conducting an exothermic reaction in thermal contact with a second heat sink using at least one of the one or more reaction products. Conducting the endothermic reaction and conducting the exothermic reaction generate a temperature difference between the first heat sink and the second heat sink.

### BRIEF DESCRIPTION OF THE DRAWING

Some implementations of the present specification will now be described, by way of example only, with reference to the attached Figures, wherein:

FIG. 1 shows a schematic representation of an example system for harnessing thermal energy.

### DETAILED DESCRIPTION

This document describes a method to harness ambient thermal energy to do useful work. In order to accomplish this, we utilize a reversible endothermic/exothermic reaction where all the reactants on one side are liquid and all the reactants on the other side are gas.

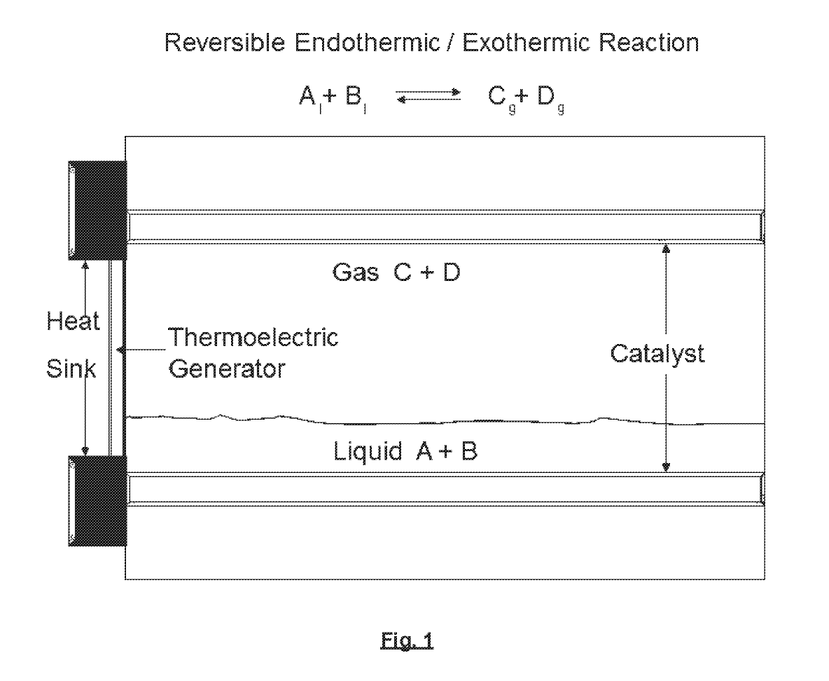

FIG. 1 shows a schematic representation of an example system for harnessing thermal energy. The concentration of A+B within the liquid will cause a net endothermic reaction at the lower catalyst. This will draw heat from the lower heat sink. The gas will bubble up and the concentration of gas C+D at the upper catalyst will cause a net exothermic reaction at the upper catalyst which will deposit heat at the upper heat sink. There is now a temperature difference between the two heat sinks. Electricity can be generated by attaching a thermoelectric generator between the two heat sinks. In some implementations, the thermoelectric generator can comprise a thermocouple. At the very least, a cooling system will have been developed.

This method can be further extended to include any reversible reactions where the products/reactants on one side are denser than upon the other side. For example, A+B can be any two fluids that are more dense than the fluids C+D. A+B can also be a combination of a solid and a fluid (gas or liquid) that is denser than the fluids C+D. The reversible reaction used can require multiple reactants/products or single reactants/products. For example, and without limitation, the left side can be comprised only of A and the right side only of D.

The benefits and advantages of creating such a technology can be as follows: energy can be generated by the heat in the atmosphere and cooling can become energy-free or requiring minimal energy. Other benefits can include, but are not limited to: generating sustainable greenhouse-friendly energy, the ability to harness energy from hostile/barren/desert environments, reduction of global energy expenditure, and potentially reducing/eliminating global warming effects.

The above-described implementations are intended to be exemplary and alterations and modifications may be effected thereto, by those of skill in the art, without departing from the scope of the invention which is defined solely by the claims appended hereto.

What is claimed is:

1. A method of harnessing ambient thermal energy comprising:
conducting an endothermic reaction in thermal contact with a first heat sink to generate one or more reaction products; and
conducting an exothermic reaction in thermal contact with a second heat sink using at least one of the one or more reaction products;
wherein the conducting the endothermic reaction and the conducting the exothermic reaction generates a temperature difference between the first heat sink and the second heat sink.
